(19) United States
(12) Patent Application Publication
(10) Pub. No.: US 2012/0090778 A1
(43) Pub. Date: Apr. 19, 2012

(54) POWDER COATING FOR PHOTOVOLTAIC MODULE

(75) Inventors: Stephen Yau-Sang CHENG, Hong Kong (HK); Ka-Lok LEUNG, Hong Kong (HK)

(73) Assignee: Du Pont Apollo Limited, Hong Kong (HK)

(21) Appl. No.: 12/906,150

(22) Filed: Oct. 18, 2010

(51) Int. Cl. H01L 31/18; H01L 31/04

(52) U.S. Cl. 156/279; 136/256

(57) ABSTRACT

Disclosed herein is a backsheet for a photovoltaic module. The backsheet includes a dielectric layer, an adhesive layer disposed on the dielectric layer, a barrier layer disposed on the adhesive layer and bonded to the dielectric layer via the adhesive layer, and a weather resistant layer directly disposed on and bonded to the barrier layer by a powder coating method.

### BACKGROUND

1. Field of Invention

The present invention relates to a photovoltaic module (PV module). More particularly, the present invention relates to a PV module having a backsheet's outermost weather-resistant layer prepared by a powder coating process.

2. Description of Related Art

PV modules are units capable of converting light energy into electrical energy. PV modules are commonly manufactured in the form of laminated structures including at least a solar cell string and an encapsulating system. The solar cell string consists of a plurality of solar cells, where the solar cells are encapsulated between a front transparent medium and a back protective sheet, called backsheet with the polymeric material bonded to the front transparent medium and backsheet. The encapsulating system is responsible for maintaining long service life of PV modules, which is of utmost interest to the industry in order to reduce the cost of solar electricity. The primary functions of backsheet include vapor/moisture barrier, UV resistance, electrical insulation, mechanical support and protection, and weathering resistance.

Conventional backsheets are multi-layered laminate sheets. In particular, a conventional backsheet may comprise, from top to bottom, a dielectric layer, a first adhesive layer, a barrier layer, a second adhesive layer, and a weather resistant layer. The weather resistant layer serves to protect the PV modules from weathering factors such as UV exposure, moisture condensation and air/oxygen permeation. Fluorinated polymers are known to be highly resistant to UV radiation and thus are widely used as the weather resistant layer in outdoor PV modules.

The lamination process for fabricating backsheets results in yield losses after each lamination step and is time-consuming. Accordingly, there exists a need in the art for providing a more cost-effective process for fabricating the backsheet for a PV module.

### SUMMARY

The following presents a summary of the disclosure in order to provide a basic understanding to the reader. This summary is not an extensive overview of the disclosure and it does not identify key/critical elements of the present invention or delineate the scope of the present invention. Its sole purpose is to present some concepts disclosed herein in a simplified form as a prelude to the more detailed description that is presented later.

In one aspect, the present invention is directed to a backsheet for a photovoltaic module. The weather resistant layer of the backsheet is formed by a powder coating method rather than conventional lamination process. Accordingly, the present weather resistant layer may adhere to the adjacent layer without the use of an additional adhesive, thereby reducing the manufacturing time and cost of the backsheet.

According to one embodiment of the present invention, the backsheet comprises a dielectric layer; an adhesive layer disposed on the dielectric layer; a barrier layer disposed on the adhesive layer and bonded to the dielectric layer via the adhesive layer; and a weather resistant layer directly disposed on and bonded to the barrier layer by a powder coating method.

In yet another aspect, the present invention is directed to a process for manufacturing a photovoltaic module, which comprises a backsheet according to the aspect and embodiment(s) of the present invention. According to this method, a weather resistant layer of the backsheet is formed by a powder coating method rather than the conventional lamination process.

According to one embodiment of the present invention, the process comprises the steps as follows. A photoelectric conversion stack film, comprising at least one solar cell is provided. An encapsulant is stacked on the back (facing away from the sun) of the photoelectric conversion stack film. The dielectric layer side of a semi-product of backsheet which comprise layers in the order of a dielectric layer, followed by an adhesive, followed by a barrier layer is stacked on the said encapsulant. A weather-resistant coating composition is then applied over the barrier layer by a powder coating method. The complete stack, including the powder coating composition is cured to obtain a photovoltaic module with a powder coated weather resistant layer.

Many of the attendant features will be more readily appreciated as the same becomes better understood by reference to the following detailed description considered in connection with the accompanying drawings.

### BRIEF DESCRIPTION OF THE DRAWINGS

The present description will be better understood from the following detailed description read in light of the accompanying drawings, wherein:

FIG. 1 is a schematic diagram illustrating a backsheet according to one embodiment of the present invention;

FIG. 2A is a schematic diagram illustrating a photovoltaic module according to one embodiment of the present invention;

FIG. 2B is a schematic diagram illustrating a photovoltaic module according to another embodiment of the present invention;

FIG. 3 is a flow chart of a manufacturing process according to one embodiment of the present invention; and

FIG. 4 is a flow chart of a manufacturing process according to another embodiment of the present invention.

Like reference numerals, where possible, are used to designate like parts in the accompanying drawings.

### DETAILED DESCRIPTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

References in the singular may also include the plural (for example, “a” and “an” may refer to one, or one or more) unless the context specifically states otherwise. The use of numerical values in the various ranges specified in this application, unless expressly indicated otherwise, are stated as approximations as though the minimum and maximum values within the stated ranges were both preceded by the word “about”. In this manner, slight variations above and below the stated ranges can be used to achieve substantially the same results as values within the ranges. Also, the disclosure of these ranges is intended as a continuous range including every value between the minimum and maximum values.

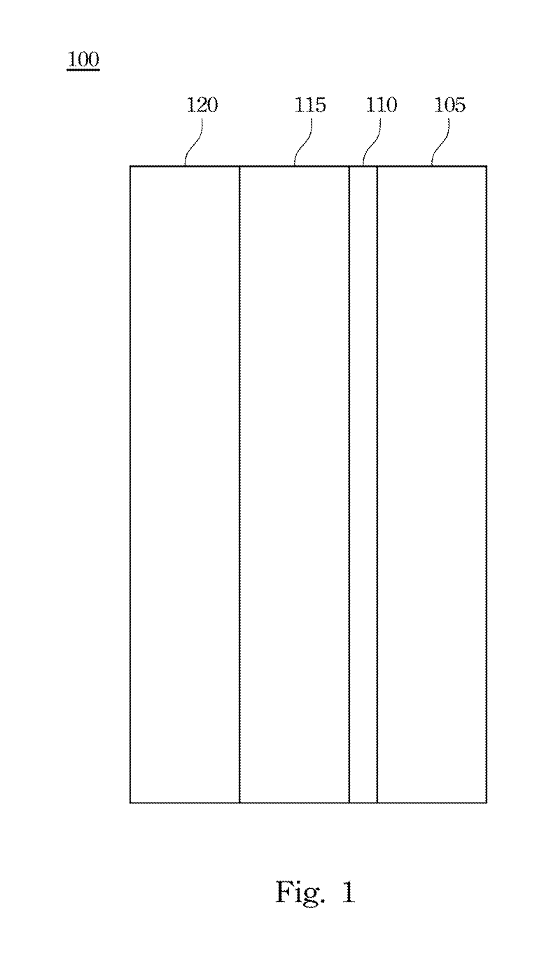

Referring to FIG. 1, the backsheet 100 according to one embodiment of the present invention comprises: a dielectric layer 105, an adhesive layer 110, a barrier layer 115 and a weather resistant layer 120. The adhesive layer 110 is disposed between the dielectric layer 105 and barrier layer 115. The weather resistant layer 120 is directly disposed on and bonded to a surface of the barrier layer 115 opposing to the dielectric layer 105 by a powder coating method.

According to the embodiments of the present invention, the dielectric layer 105 may be made from any material which acts as an electrical insulator, and is preferably a polymeric dielectric layer. One example of the polymeric dielectric layer is a polyester. Examples of polyester include, but are not limited to: polyethylene terephthalate, polybutylene terephthalate, polyethylene naphthalate and styrene-polyester copolymer. Alternatively, the polyester dielectric layer may be an oriented polyester film, such as a bi-axially-oriented polyester film. Other illustrative examples of polymer for forming the polymeric dielectric layer may include polycarbonate, cyclic polyolefins, polyamides, polyurethanes, acrylics, polyacrylate, metallocene-catalyzed and the like.

In accordance with the present invention, the adhesive layer 110 may comprise any material that is suitable to bond the barrier layer 115 to the dielectric layer 105. Examples of such material include, but are not limited to amino-functional silanes, glycidoxy-functional silanes, poly(allyl amines), and poly(vinyl amines).

The barrier layer 115 used herein may serve as a moisture and/or oxygen barrier layer that prevent the permeation of moisture/water vapor. In one example, the barrier layer is a metal foil. The metal foil may, for example, be made of steel, copper, aluminum or alloy thereof. Alternatively, the barrier layer 115 may be formed of a metal oxide, which may be but not limited to aluminum oxide and silicon oxide; still alternatively, the barrier layer may be a polymeric layer, which may be but not limited to parylene, polyimide, polyacrylamide, epoxy, polystyrene, poly(vinyl alcohol), poly(vinylidene chloride), poly(vinyl chloride), polyvinylidene fluoride, and acrylonitrile.

Optionally, the barrier layer 115 may be pre-treated to remove contaminations such as oil, dirt, etc, as well as improve the adhesion and other physical properties of the barrier layer 115. One example of the surface pre-treatment of the barrier layer 115 is galvanization, which may provide the barrier layer 115 with a better corrosion resistance. Alternatively, the barrier layer 115 may be subjected to a chromate or phosphate surface finishing treatment to prevent corrosion and improve adhesion. In another example, the barrier layer 115 may also be primed with polymeric material(s), such as ethylene acrylic acid copolymers or ethylene maleic anhydride copolymers, to improve its adhesion to other polymeric materials.

One embodiment of the present disclosure is characterized in that the backsheet 100 further comprises a weather resistant layer 120 formed by a powder coating method. Generally, suitable coating composition for forming the weather resistant layer 120 may comprise a thermosetting powder resin and a powder crosslinker. Examples of the thermosetting powder resin include, but are not limited to polyurethane-based resins, polyurethane-acrylic based resins, polyester-based resins, epoxies, and polyester-epoxy hybrids. Of course, other thermosetting resins capable of providing ultraviolet resistance, chemical resistance, and/or weatherability may also be used. The weight ratio of the thermosetting powder resin to the powder crosslinker is about 90:10 to about 98:2.

In one example, the thermosetting powder resin is a carboxyl functional polyester, such as commercially available polyesters, examples of which include but are not limited to: Crylcoat® 2682-1, Crylcoat® 4488-0, Crylcoat® 4430-0, Crylcoat® 4659-0 and Crylcoat® 4540 (manufactured by Cytec Industries Inc., New Jersey, US), and Uralac® P880, Uralac® P883 and Uralac® P3220 (manufactured by Powder Coating Resins, AP Zwolle, Netherlands).

Illustrative examples of the powder crosslinker include, but are not limited to Primid® XL-552 (manufactured by Rohm and Haas Australia Pty Ltd), triglycidyl isocyanurate (TGIC) and Araldite® PT 910 (manufactured by Huntsman International LLC).

The curing temperature and curing time of some thermosetting powder resin and powder crosslinker combinations according to some embodiments of the present invention are summarized in Table 1.

TABLE 1

| Thermosetting | Powder | Resin/Cross- | Curing | Curing Time |
|---|---|---|---|---|
| powder resin | crosslinker | linker Ratio | Temp (° C.) | (min) |
| Crylcoat 2682-1 | Primid XL 552 | 95/5 | 180 | 10-15 |
| Crylcoat 4488-0 | TGIC | 93/7 | 200 | 10 |
| Crylcoat 4430-0 | TGIC | 93/7 | 200 | 10 |
| Crylcoat 4659-0 | TGIC | 93/7 | 200 | 10 |
| Crylcoat 4540 | Araldite PT910 | 93/7 | 200 | 10 |
| Uralac P880 | Primid XL 552 | 95/5 | 180 | 10-15 |
| Uralac P883 | Primid XL 552 | 96/4 | 180 | 10-15 |
| Uralac P3220 | Primid XL 552 | 93/7 | 160 | 15 |

Optionally, the coating composition for forming the weather resistant layer 120 may further comprise additives that may be uniformly mixed with the thermosetting powder resin. For example, the additives may include, but are not limited to: pigments, light stabilizers, flowing agents, fillers (such as barium sulphate), anti-yellow agents (such as benzoin), reflective materials or hardners.

The pigments may be used to furnish the resultant weather resistant layer 120 with a desired color. Illustrative examples of the pigments include, but are not limited to: titanium dioxide (white), carbon black (black), iron oxide (such as Bayferrox® 303T black pigment and Bayferrox® 645T brown pigment). When pigments are utilized, the coating composition contains at least about 0.05 wt % and up to about 10 wt % of pigments, based on the total weight of the coating composition.

The light stabilizer may be an ultraviolet absorber (such as Tinuvin® 326, Tinuvin® 327 and Tinuvin® 328 by Ciba-Geigy Corp.) for preventing the UV degradation of weather resistant layer 120, or a hindered-amine light stabilizer (such as Tinuvin® 292, Tinuvin® 622 and Tinuvin® 770 by Ciba-Geigy Corp.) for trapping free radicals formed within the weather resistant layer 120 so as to prevent cracking and chalking thereof. When light stabilizers are utilized, the coating composition contains at least about 0.05 wt % and up to about 10 wt % of light stabilizers, based on the total weight of the coating composition.

The flowing agent may be used to increase the flow, leveling and dispersing properties in the coating composition. Illustrative examples of the flowing agent include, but are not limited to DY-88 and TP 503. When flowing agents are utilized, the coating composition contains at least about 0.05 wt % and up to about 10 wt % of flowing agents, based on the total weight of the coating composition.

By adding a reflective material as an additive, the weather resistant layer 120 thus-obtained may be reflective. Besides, by adding a hardener as the additive, the resultant weather resistant layer 120 may be provided with better mechanical properties such as abrasion resistance.

Generally, the coating composition may comprise at least about 50 wt % up to about 100 wt % of the thermosetting powder resin and the powder crosslinker, based the total weight of the coating composition. Specifically, the thermosetting powder resin and the powder crosslinker may have a weight percent of about 50, 55, 60, 65, 70, 75, 80, 85, 90, 95 or 100 wt %.

Besides, the coating composition may comprise up to about 50 wt % of the additive(s), based the total weight of the coating composition. Specifically, the additive(s) may have a weight percent of about 0, 5, 10, 15, 20, 25, 30, 35, 40, 45 or 50 wt %.

Exemplary embodiments of the coating composition comprising various additives and weight ratios thereof are summarized in Table 2.

TABLE 2

| | Example 1 | Example 2 | Example 3 | Example 4 |
|---|---|---|---|---|
| Resin + Crosslinker | 60 | 60 | 60 | 60 |
| Benzoin | 0.5 | 0.5 | 0.5 | 0.5 |
| TiO₂ | 10 | 20 | 0 | 0 |
| Bayferrox 303T | 0 | 0 | 5 | 10 |
| Flowing agent | 5 | 10 | 5 | 10 |
| Tinuvin 900 | 1 | 3 | 1 | 3 |
| Tinuvin 144 | 0.5 | 2 | 0.5 | 2 |
| Barium Sulphate (BaSO₄) | 23 | 4.5 | 28 | 14.5 |

In the examples listed in Table 2, the appearances of the coating compositions of examples 1 and 2 are white, whereas the appearances of the coating compositions of examples 3 and 4 are black.

According to the embodiments of the present invention, the weather resistant layer 120 may have a thickness of at least 10-1000 μm. For example, the thickness of the weather resistant layer 120 may be about 10-500 μm; preferably about 40-200 μm; and more preferably about 60-120 μm. Specifically, the thickness of the weather resistant layer 120 may be about 10, 15, 20, 25, 30, 35, 40, 45, 50, 55, 60, 65, 70, 75, 80, 85, 90, 95, 100, 150, 200, 250, 300, 350, 400, 450, 500, 550, 600, 650, 700, 750, 800, 850, 900, 950, or 1000 μm.

Generally, powder coating is applied directly as dry powder, for example, the coating composition consisting of dry powder is directly applied to a surface of a part which is to be coated. Frequently employed methods for powder coating include electrostatic-charging spray coating or triboelectric-charging spray coating. Detailed description regarding the powder coating method for forming the weather resistant layer 120 is provided hereinbelow.

In another aspect, the present invention is directed to a photovoltaic module comprising a backsheet according to the above-described aspect/embodiments of the present invention. The backsheet can, for example, be the backsheet 100 shown in FIG. 1.

Within the scope of the present invention, a solar cell is meant to include any article which can convert light into electrical energy. Generally, solar cells can be categorized into crystalline solar cells and thin film solar cells; however, this should not be considered to be limiting the scope of the present invention. The photovoltaic material used in crystalline solar cells may be monocrystalline silicon, polycrystalline silicon or microcrystalline silicon.

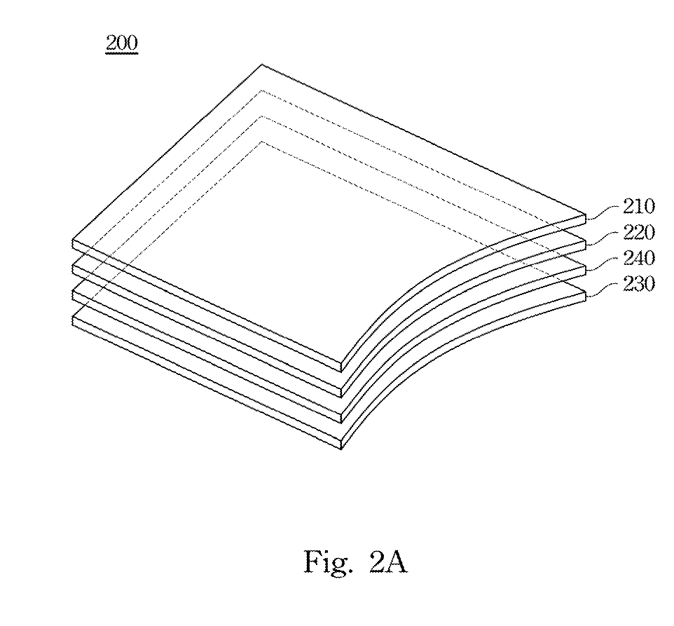

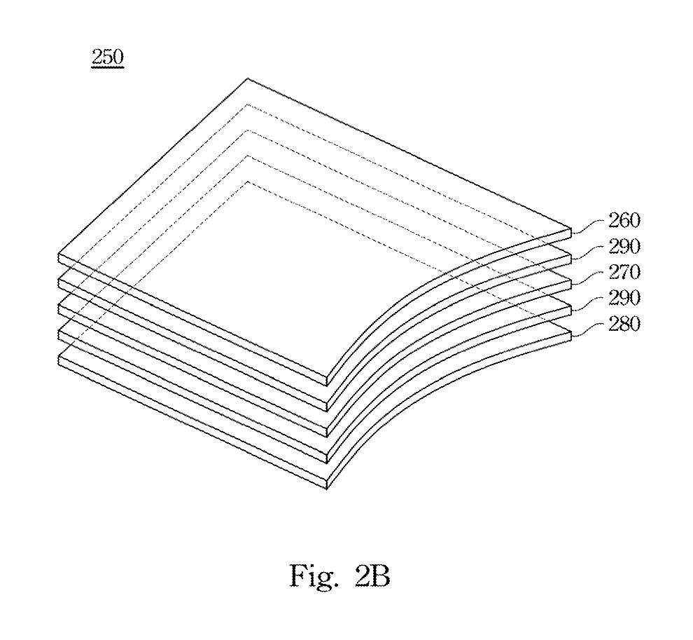

FIG. 2A and FIG. 2B are schematic diagrams illustrating thin film photovoltaic module 200 and crystalline photovoltaic module 250 respectively, according to embodiments of the present invention, respectively.

Reference is made now to FIG. 2A, the photovoltaic module 200 may include: a front substrate 210, a photoelectric conversion stack film 220, a backsheet 230 and an encapsulant layer 240. As described hereinabove, the photoelectric conversion stack film 220 comprises at least one thin film solar cell, which is directly deposited on the front substrate 210. The backsheet 230 is bonded to the photoelectric conversion stack film 220 with the encapsulant 240, wherein the dielectric layer 105 of the backsheet 230 directly contacts with the encapsulant 240.

In FIG. 2B, the photovoltaic module 250 may include: a front substrate 260, a photoelectric conversion stack film 270, a backsheet 280, and two encapsulant layers 290. As described herein-above, the photoelectric conversion stack film 270 comprises at least one crystalline solar cell. Hence the photoelectric conversion stack film 270 should be bonded to the front substrate 260 with an adhesive layer. In this case, the encapsulant layers 290 are responsible for respectively bonding the front substrate 260 and the backsheet 280 to the photoelectric conversion stack film 270.

The front substrate 210 or 260 is formed of a light-transmitting material, such as but not limited to a glass plate, a polymeric film. The photoelectric conversion stack film 220 may comprise one or more electrically interconnected thin film solar cells in series and/or parallel. Thin film solar cells are produced by depositing one or more thin layers of photovoltaic material on a substrate. Thin-film solar cells are usually categorized according to the photovoltaic material used: amorphous silicon (a-Si) and other thin-film silicon, copper indium selenide (CIS), cadmium telluride (CdTe), and dye sensitized solar cells (DSC) and other organic solar cells. The photoelectric conversion stack film 270 may comprise one or more electrically interconnected crystalline solar cells in series and/or parallel. In one embodiment, the backsheet 230 or 280 may be the backsheet 100 described hereinabove, and accordingly, the detailed description regarding the backsheet is omitted for the sake of brevity.

The encapsulant layer 240 or 290 may be formed of at least one polymeric material, such as, acid copolymers, ethylene (meth)acrylic acid copolymer, ionomers, ethylene vinyl acetate (EVA), acoustic poly(vinyl acetal), acoustic poly(vinyl butyral), polyvinylbutyral (PVB), thermoplastic polyurethane (TPU), polyvinylchloride (PVC), metallocene-catalyzed linear low density polyethylenes, polyolefin block elastomers, ethylene acrylate ester copolymers (e.g., poly(ethylene-co-methyl acrylate) and poly(ethylene-co-butyl acrylate)), silicone elastomers, epoxy resins and combinations thereof. In one example, the encapsulant layer 240 or 290 may comprise EVA. It is appreciated that the PV module 200 or 250 may comprise additional components such as a photovoltaic metallization sheet, a junction box and other structural parts. However, for the sake of clarity, those components are omitted in the diagram provided herein.

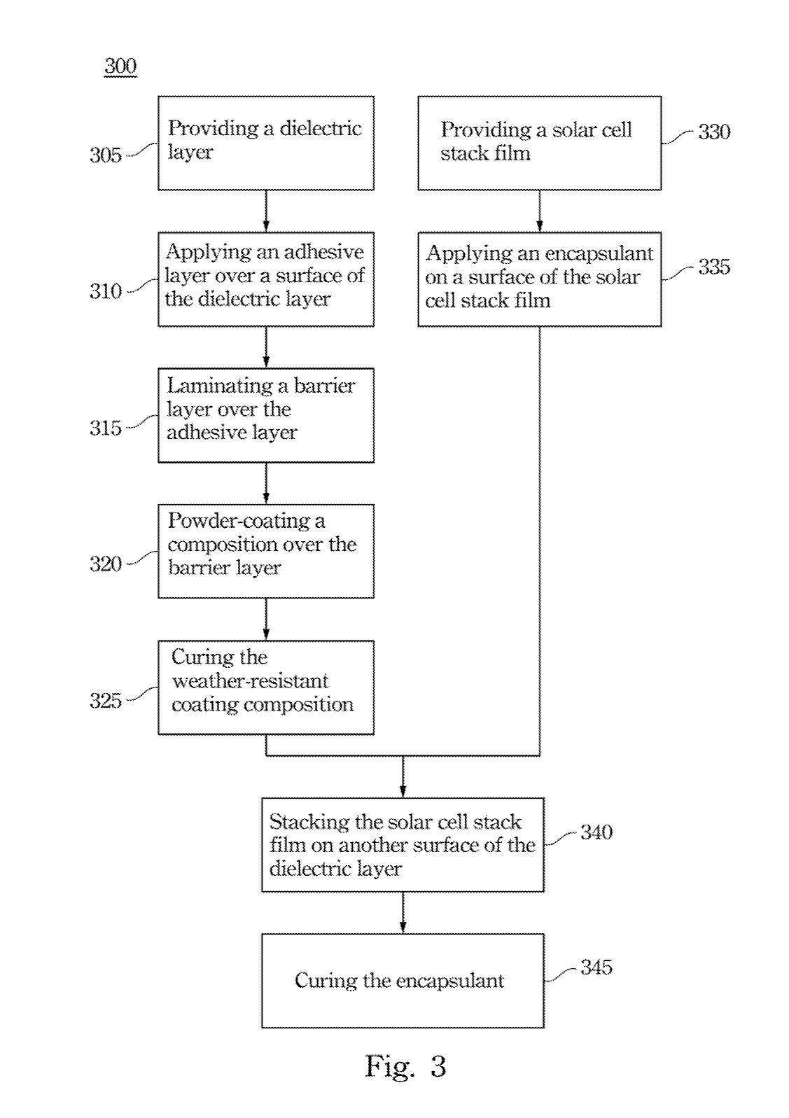

Now that the structures of the backsheet and photovoltaic module have been described, the process for manufacturing a photovoltaic module comprising such a backsheet is discussed with reference to FIG. 3, which is a flow chart illustrating the manufacturing process 300 according to one embodiment of the present invention. It should be noted that the processes disclosed herein comprise one or more steps or actions for achieving the described process. The steps and/or actions may be interchanged with one another without departing from the scope of the claims.

In step 305, a dielectric layer is provided. In step 310, an adhesive layer is applied over one side of the dielectric layer. In step 315, a barrier layer is laminated over the adhesive layer whereby the barrier layer bonds to the dielectric layer via the adhesive layer.

Moreover, an optional pretreatment step may be performed after step 315 or before step 315. Generally, the underlying part to be coated (in this case, the barrier layer) may be pre-treated to remove contaminations such as oil, dirt, etc, as well as to improve the adhesion of the coating. The pretreatment can be done by such as chemical or mechanical methods depending on the size and the material of the part to be powder coated, the type of soil to be removed and the performance requirement of the finished product.

In step 320, a weather-resistant coating composition is applied over a surface of the barrier layer opposite to the dielectric layer by a powder coating method. Suitable coating compositions used herein may comprise a thermosetting powder resin and a powder crosslinker, which has been described above, and thus the detailed descriptions are omitted herein for the sake of clarity. Generally, the powder is charged and applied directly to the surface of the barrier layer, which is preferably pretreated. Currently, the most common way of applying the coating compositions to the underlying part is to spray the powder using an electrostatic gun, or Corona gun. Corona gun imparts a positive electric charge on the powder, which is then sprayed towards the underlying part by mechanical or compressed air spraying and then accelerated toward the underlying part by electrostatic charge. Another type of gun is called a Tribo gun, which charges the powder by triboelectric friction. Generally, powder moving through the gun rubs against the charging module in the Tribo gun and gets charged. The material of the charging module can be selected depending on the formulation of the coating composition. Particle size of the powder of the coating composition may affect the charging level of the powder and the uniformity and smoothness of the resultant layer. According to embodiments of the present invention, the particles of the coating composition may have a diameter of about 10-200 μm.

During the powder coating step, a mask is optionally provided so as to prevent the powder from reaching the other side of the dielectric layer and the lateral side of the laminated stack. The mask may be made of a polymeric material.

In FIG. 3, the manufacturing process 300 proceeds to step 325, where the weather-resistant coating composition, after being sprayed over the surface of the barrier layer, is cured to obtain a weather resistant layer. Upon the completion of step 325, a finished backsheet (for example, backsheet 100) for use in a photovoltaic module is obtained.

During the curing step, the thermosetting powder resin would melt when the temperature reaches the glass transition temperature (Tg) thereof, and then chemically reacts with the powder crosslinker to form a higher molecular weight polymer in a network-like structure. Also, the curing step facilitates the adhesion of the weather resistant layer to the barrier layer. The curing step may be performed in an oven at a suitable curing temperature for a sufficient time. Examples of ovens for performing the curing step may be a conventional oven or an infrared oven. It is appreciated that the curing behavior, including the curing temperature and curing time, may vary depending on the formulation of the coating composition.

According to the principles of the spirits of the present invention, the curing temperature can be about 140-200° C., preferably about 160-180° C. Specifically, the curing temperature may be about 140, 145, 150, 155, 160, 165, 170, 175, 180, 185, 190, 195 or 200° C. Also, the curing time may be about 20-60 minutes, for example, about 20, 25, 30, 35, 40, 45, 50, 55 or 60 minutes.

In one optional embodiment, the weather-resistant coating composition may be formulated so that the curing behavior thereof matches the curing behavior of the encapsulant of the PV module. As such, the weather-resistant coating composition and the encapsulant may be cured at a same curing temperature for a same curing time.

Turning back to FIG. 3, the manufacturing process 300 also includes a step 330, where a photoelectric conversion stack film is provided. The solar cell stack film, like the photoelectric conversion stack film 220 described hereinabove comprises one or more electrically interconnected solar cells. As an illustrative example, step 330 for manufacturing the photoelectric conversion stack film may comprise steps as follows. First, a front substrate having a transparent conductive oxide layer formed there on is provided. Then, a thin-film semiconductor layer is formed on the transparent conductive oxide layer by deposition techniques. Subsequently, a conductive electrode is formed on the thin-film semiconductor layer, such that the photoelectric conversion stack film is completed. It should be noted that the descriptions hereinabove regarding the photoelectric conversion stack film 220 and the front substrate 210 of FIG. 2A are equally applicable in the manufacturing process 300.

In step 335, an encapsulant is applied on the back side of the photoelectric conversion stack film. Examples of the encapsulant 240 described hereinabove are also applicable herein. Thereafter, in step 340, the photoelectric conversion stack film is stacked on the front side of the dielectric layer of the finished backsheet. In step 345, the encapsulant is cured so that the photoelectric conversion stack film bonds to the dielectric layer and a photovoltaic module (such as the PV module 200) is obtained.

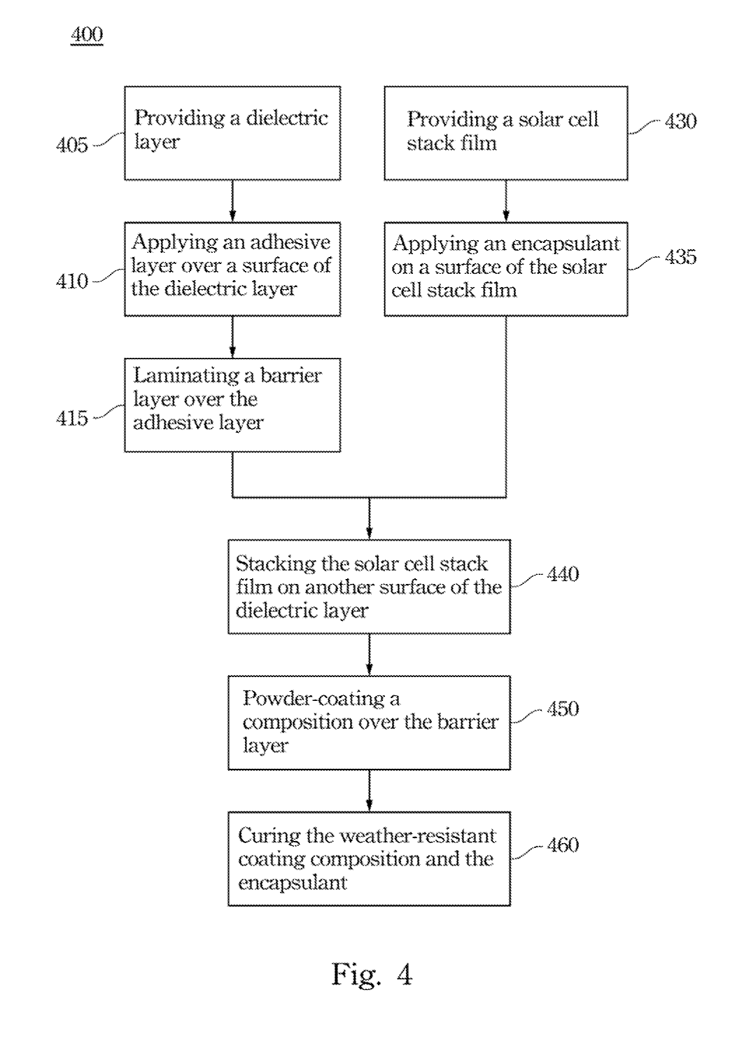

FIG. 4 is a flow chart illustrating a manufacturing process 400 according to another embodiment of the present invention. In this embodiment, the weather-resistant coating composition and the encapsulant are cured simultaneously. Steps 405, 410 and 415 are respectively the same as steps 305, 310 and 315 and thus the detailed descriptions are omitted herein for the sake of clarity. Steps 430 and 435 are respectively the same as steps 330 and 335, and will not describe the detail herein for the sake of clarity.

Step 440 is similar to step 340, except that the photoelectric conversion stack film is stacked on the other side of the dielectric layer of the semi-finished backsheet. In step 450, a weather-resistant coating composition is applied over a surface of the barrier layer opposite to the dielectric layer by a powder coating method. Afterwards, in step 460, the weather-resistant coating composition and the encapsulant are cured. As such, a photovoltaic module is obtained.

It should be appreciated that since the weather-resistant coating composition and the encapsulant are cured simultaneously in this embodiment, it is preferred that the weather-resistant coating composition is formulated so that the curing behavior thereof matches the curing behavior of the encapsulant of the PV module.

It is understood that the above description of embodiments is given by way of example only and that various modifications may be made by those with ordinary skill in the art. The above specification, examples and data provide a complete description of the structure and use of exemplary embodiments of the invention. Although various embodiments of the invention have been described above with a certain degree of particularity, or with reference to one or more individual embodiments, those with ordinary skill in the art could make numerous alterations to the disclosed embodiments without departing from the spirit or scope of this invention.

What is claimed is:

1. A backsheet for a photovoltaic module, comprising:
a dielectric layer;
an adhesive layer disposed on the dielectric layer;
a barrier layer disposed on the adhesive layer and bonded to the dielectric layer via the adhesive layer; and
a weather resistant layer directly disposed on and bonded to the barrier layer by a powder coating method.

2. The backsheet of claim 1, wherein the dielectric layer is a polyester dielectric layer.

3. The backsheet of claim 2, wherein the polyester dielectric layer comprises a material selected from the group consisting of: polyethylene terephthalate, polybutylene terephthalate, polyethylene naphthalate, and styrene-polyester copolymer.

4. The backsheet of claim 1, wherein the barrier layer is a metal foil, metal oxide, or a polymeric layer.

5. The backsheet of claim 4, wherein the metal foil comprises a material selected from the group consisting of steel, copper, aluminum and alloy thereof.

6. The backsheet of claim 1, wherein the weather resistant layer is formed from a coating composition comprising a thermosetting powder resin and a powder crosslinker, the thermosetting powder resin selected from the group consisting of polyurethane-based resins, polyurethane-acrylic based resins, polyester-based resins, epoxies, and polyester-epoxy hybrids.

7. The backsheet of claim 6, wherein the coating composition further comprises an additive.

8. The backsheet of claim 1, wherein the weather resistant layer has a thickness of about 10-1000 μm.

9. The backsheet of claim 1, wherein the powder coating method is an electrostatic-charging spray coating or a triboelectric-charging spray coating.

10. A process for manufacturing a photovoltaic module, comprising the steps of:
providing a dielectric layer, wherein the dielectric layer has a first surface and a second surface;
applying an adhesive layer over the first surface of the dielectric layer;
laminating a barrier layer over the adhesive layer whereby bonding the barrier layer to the dielectric layer;
applying a weather-resistant coating composition over the barrier layer by a powder coating method;
providing a photoelectric conversion stack film on the second surface of the dielectric layer, wherein the photoelectric conversion stack film comprising a solar cell and an encapsulant; and
performing at least one curing process whereby forming a weather resistant layer and bonding the photoelectric conversion stack film to the dielectric layer via the encapsulant.

11. The process of claim 10, wherein the step of performing at least one curing process comprises a first curing process and a second curing process, wherein the first curing process is for curing the weather-resistant coating composition to form the weather resistant layer and the second curing process is for curing the encapsulant to bond the photoelectric conversion stack film to the dielectric layer.

12. The process of claim 10, wherein the step of performing at least one curing process comprises curing the weather-resistant coating composition and the encapsulant simultaneously.

13. The process of claim 10, wherein the encapsulant comprises ethylene vinyl acetate.

14. The process of claim 10, wherein the weather-resistant coating composition has a curing behavior matches the curing behavior of the encapsulant.

15. The process of claim 10, wherein the weather-resistant coating composition comprises a plurality of particles each having a diameter of about 10-200 μm.

16. The process of claim 10, wherein the weather resistant layer has a thickness of about 10-1000 μm.

17. The process of claim 10, wherein the weather-resistant coating composition comprises a material selected from the group consisting of: polyurethane-based resins, polyurethane-acrylic based resins, primid-based resins, polyester-based resins, epoxies, and polyester-epoxy hybrids.

18. The process of claim 10, wherein the powder coating method is an electrostatic-charging spray coating or a triboelectric-charging spray coating.
